(19) United States
(12) Patent Application Publication
(10) Pub. No.: US 2010/0110536 A1
(43) Pub. Date: May 6, 2010

(54) OPTICAL AMPLIFIER AND PRODUCTION METHOD THEREOF

(75) Inventors: Keiichi Nashimoto, Ayase-shi (JP); Yoshiyuki Sugahara, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: EpiPHOTONICS CORP., Ayase (JP)

(21) Appl. No.: 12/525,813

(22) PCT Filed: Feb. 5, 2008
(86) PCT No.: PCT/JP2008/051828

§ 371 Date: Aug. 21, 2009

(30) Foreign Application Priority Data
Feb. 5, 2007 (JP) 2007-025691

(51) Int. Cl. H01S 3/00; G02B 6/10; H01L 33/00

(52) U.S. Cl. 359/341.5; 438/31; 257/E33.067

(57) ABSTRACT

A small-sized, highly efficient optical amplifier having a PLZT optical waveguide layer to which a rare earth element is added, and a method for manufacturing the same are provided. Disclosed is an optical amplifier including an optical waveguide layer, the optical waveguide layer including Pb₁₋ₓLaₓ(Zr_{y}Ti_{1-y})_{1-x/4} O₃ (PLZT: 0<x<0.3, 0<y<1.0), being doped with Yb (ytterbium) in an amount of from 0.2 mol % to 11.0 mol %, and being a single crystal film formed by solid-phase epitaxial growth.

### TECHNICAL FIELD

The present invention relates to an optical function device using a PLZT waveguide, for example, a waveguide type optical amplifier that has an amplifying function that amplifies light transmitted by optical fiber without optical-electric conversion, and a production method thereof.

### BACKGROUND ART

Optical communications networks are in the process of being developed, from point to point optical communication connecting individual inter-nodes, into optical communication carrying out Add-Drop Multiplexing between points, and also optical communication connecting plural inter-nodes just with an optical signal, without converting to an electrical signal. Also, since volumes of traffic and functionality of optical communications networks are increasing, multiplexing of plural wavelengths in a single strand of optical fiber, and, the opposite thereof, of dividing optical signals of plural wavelengths being transmitted in a single strand of optical fiber into their individual wavelengths (WDM: Wavelength Division Multiplexing), have been put into practice.

In these methods, it is necessary to transmit optical signals with different wavelengths from each other in a single strand of optical fiber, and to carry out intermediate relay amplifying according to the transmitting distance without converting into electrical signals. Optical amplifiers, for carrying out long haul transmissions without conversion from optical into electrical signals, support optical networks.

As optical amplifiers, optical fiber amplifiers with optical amplification media of optical fibers in which a rare earth element has been added to the core, for example Er (erbium) Doped Optical Fiber Amplifiers (EDFA), have been put into practice, and application of such amplifiers to optical communications is continuing to progress at a fast pace. Such EDFAs are operated in the 1.55 μm wavelength band where the loss in silicon dioxide based optical fibers is at a minimum, and are known for their superior characteristics of high gain of 30 dB or more, low noise, wide gain band, lack of polarization dependence in the gain, high saturation power output, and the like.

However, EDFAs are optical fibers of around 10 m in length, and have the problem that it is difficult to make the devices themselves small. Therefore, for the future, effort is being put into advancing development of optical amplifiers in waveguide form using, in optical waveguides, materials with rare earth elements added that can be used as amplification media at the desired wavelength band, taking into consideration of miniaturization of optical amplifiers including miniaturization of optical amplifiers which include laser light sources for excitation, integration or unifying of plural optical amplifier units, and modularization of high-performance devices with modulators, switches, wavedividers and the like integrated onto a single substrate to reduce the size.

An optical switch is one of the most important components, and as a component that, for example, is used for switching between plural optical fibers according to demand, or used for switching to secure a diversion route when there is damage to a network. Optical waveguide switches that are superior in being miniaturized are generally formed as channel optical waveguides in LiNbO₃, semiconductor compounds, quartz, or polymers, and are provided with an optical switch for electrically controlling the light progress direction at the intersection portions of each of the paths, or with an optical gate for electrically controlling, open or close, the progress of the light.

Optical switches using quartz or a polymer, are made with a core size that is about the same size as the mode field diameter, and have the characteristic that the insertion loss is low because the optical coupling efficiency from the optical fiber is good. However, there is the problem that, since electrical current is applied to a heater provided on the surface of the optical waveguide to change the direction of light progression using a change in refractive index due to the thermo-optical effect, the reaction time of such optical switches is slow. Furthermore, in order to use such a heating method with a heater, several hundreds of mW of power is consumed for the single electrode, and there is the problem that fields of use are limited.

Other than these, there are optical waveguide optical switches that use organic nonlinear optical materials. By a structure of an optical waveguide of a field poled polymer or the like, sandwiched between upper and lower electrodes, an optical switch that can be driven at a low voltage can be configured, but field poled polymers have the problem of temperature stability when compared to ferroelectric oxide materials, and, in reality, are not readily applicable.

In the case of optical waveguide optical switches using compound semiconductors and quantum wells, increasing speeds is possible, and there is the expectation of reducing the driving voltage since voltage can be applied above and below the optical waveguide core. However, there is the problem that the insertion loss is high because the optical coupling efficiency from the optical fiber is poor due to the small core size, and effort is being put into various areas. As well as this, there is the problem that the switching characteristics are inferior due to the occurrence of light absorption when switching by applying an electric field, and there are problems such as, since wafer size is limited, it is difficult to configure large scale matrixes of optical switches.

The most typically used materials for optical switches are ferroelectric oxide materials, and in the case of one of them, LiNbO₃, if voltage is applied to electrodes of an optical switch then, due to the electro-optical effect, there is a change in the refractive index, and by this the conditions of the light can be changed at high speed, and depending on the set conditions, the progression direction of the light is changed. Because of this, in an optical switch it is possible to selectively output light that entered from two input terminals to two respective output terminals. Optical switches using LiNbO₃ may be produced by making a Ti-diffusion type waveguide or a proton exchange type waveguide on a single crystal wafer, and the core size can be made to be about the same as the optical fiber mode diameter, therefore, since the optical coupling efficiency is good, insertion loss is small, and such optical switches are known as workable optical switches.

However, since it is a configuration in which coplanar electrodes are disposed on the optical waveguide faces and voltage is applied, the larger the distance between electrodes, the less optimal the field profile. In order to have no polarization dependence present the driving voltage becomes high, at 40 volts, and so that the driving voltage does not become even more extremely high, usually a long electrode of 7 mm or more is required. Further, in order to make a waveguide to a single crystal wafer by diffusion of Ti or proton exchange, it is not possible to make the effective refractive index of the channel optical waveguide high enough compared to the refractive index of the surroundings, and not possible to make the difference in refractive index high. Due to this, the need arises to make the radius of curvature of the channel optical waveguide as big as 50 mm, and, in the example of an 8×8 optical switch matrix, the size of becomes about 70 mm.

As above, whichever of LiNbO₃, compound semiconductors, quartz or polymers are used, it was not possible to obtain an optical waveguide matrix optical switch which satisfies at the same time all of the characteristics of optical switch size, driving voltage (or driving current or power consumption), switching speed, cross-talk, insertion loss, and temperature stability.

As a material for solving these problems, PLZT, that is Pb₁₋ₓLaₓ(Zr_{y}Ti_{1-y})_{1-x/4} O₃ (PLZT: 0<x<0.3, 0<y<1.0), is attracting attention for optical waveguides, and optical switches are in the process of being developed with high speed, low driving voltage, low power consumption, small size.

However, regarding PLZT ceramics, there is information about investigations into the photoluminescence characteristics thereof, according to Ballato et al. (J. Luminescence, 86 (2000) p.p. 101-105), but PLZT waveguide optical amplifiers have not been investigated. Therefore, the appropriate doping amounts and doping methods relating to rare earth element-doping were not known, and configuring an optical amplifier was difficult.

That is to say, with the aim of raising the amplification efficiency and making optical amplifiers of smaller size, or increasing the width of the amplification wavelength band, it is necessary to increase the concentration of rare earth ions, for example Er³⁺ ions added per unit volume, but generally, when the concentration is increased, a condition occurs in which multiple Er³⁺ ions exist in clusters, and this is an impediment to increasing the amplification efficiency.

Therefore, for investigations into the optical amplifiers with PLZT waveguides as the medium, in order to raise the amplification efficiency and also increase the width of the amplification wavelength band, when increasing the concentration of rare earth ions, for example Er³⁺ ions, added into a PLZT waveguide layer (core layer), it is necessary to consider the optimum concentration that can suppress clusterization of the added Er³⁺ ions, and also to consider methods of forming an Er-doped PLZT film optical waveguide. In quartz and Al₂O₃ waveguides, it is possible to form an optical amplifier component using film forming methods such as chemical vapor deposition (CVD) methods, flame hydrolysis deposition (FHD) methods, sputtering methods, vapor deposition methods, and the like, and adding a rare earth to the raw material gases, sputtering targets, or vapor sources.

However, if the rare earth is added at a certain concentration or above, in whichever of the film forming methods, defects develop such as precipitation out, and the addition amount of the rare earth species becomes about 1 mol %. For example, in the Er-doped Al₂O₃ waveguide optical amplifier formed by sputtering and reported by Musa et al. (IEEE J. Quantum Electronics, Vol. 36, No. 9 (2000) p.p. 1089-1097) Er-doping was carried out up to a concentration of 0.74 mol %, and a net gain of 1.0 dB/cm was reported. However, since a concentration of such a level is not able to obtain sufficient optical amplifying efficiency, waveguides for optical amplifier use must be elongated.

Furthermore, when investigating PLZT waveguide optical amplifiers, it is necessary to achieve a state of containment of more of the internally amplified light within the optical waveguide layer (core layer), and also necessary to reduce the overall loss. Specifically, it is necessary to achieve conditions of the waveguide in which a predetermined difference in refractive index between the core and the surrounding cladding is achieved.

Non-patent Literature 1: J. Luminescence, 86 (2000) p.p. 101-105

Non-patent Literature 2: (IEEE J. Quantum Electronics, Vol. 36, No. 9 (2000) p.p. 1089-1097

### DISCLOSURE OF INVENTION

### Problems to be Solved by the Invention

In order to solve the above described conventional problems, the present invention has an object to provide an optical amplifier including a PLZT optical waveguide layer with added rare earth element, the optical amplifier being one of small size and high efficiency, and a production method for the same.

### Means to Solve the Problems

The above described problems can be solved by the following means.

That is, the optical amplifier of the present invention comprising an optical waveguide layer, the optical waveguide layer comprising Pb₁₋ₓLaₓ(Zr_{y}Ti_{1-y})_{1-x/4} O₃ (PLZT: 0<x<0.3, 0<y<1.0), being doped with Yb (ytterbium) in an amount of from 0.2 mol % to 11.0 mol %, and being a single crystal film formed by solid-phase epitaxial growth.

The optical waveguide layer may be doped with Er (erbium) in an amount of 3.0 mol % or less, in addition to Yb (ytterbium).

The optical amplifier may comprise a buffer layer and a cladding layer in addition to the optical waveguide layer, wherein the optical waveguide layer, the buffer layer and the cladding layer each comprise a PLZT composition and the respective PLZT compositions are different from each other.

In the optical amplifier, the optical waveguide layer may comprise a channel-shaped optical waveguide layer.

The method of producing an optical amplifier of the present invention is a method of producing the optical amplifier of the present invention and the method comprises:

forming, on a substrate, an amorphous film as an optical waveguide layer precursor; and

heating the amorphous film to form the optical waveguide layer by epitaxial growth.

The optical amplifier production method of the present invention may further comprise performing etching on at least one portion of the amorphous film or the optical waveguide layer, to form a channel-shaped optical waveguide layer.

In the optical amplifier production method of the present invention, the forming of the amorphous film preferably comprises forming an amorphous film by coating an optical waveguide layer precursor solution onto the substrate, and heating.

### EFFECT OF THE INVENTION

According to the present invention, it is possible to provide an optical amplifier with a rare earth element-added PLZT optical waveguide layer, the optical amplifier being of small size and high efficiency, and a production method thereof.

### BRIEF DESCRIPTION OF THE DRAWINGS

FIG. 1 A diagram showing photoluminescence patterns for PLZT epitaxial films doped with Er and Yb.

FIG. 2 A diagram showing the photoluminescence patterns for PLZT epitaxial films doped with Er and Yb.

FIG. 3 A diagram showing the root mean square (rms) surface roughness for Er doping amounts in PLZT epitaxial films doped with Er and Yb.

FIG. 4 An outline perspective view of an example of an optical amplifier according to the present invention.

FIG. 5 A cross-sectional diagram taken on A-A in FIG. 4.

FIG. 6 A diagram showing the optical loss and optical gain (gross gain, net gain) for Yb-doping amounts in PLZT epitaxial films doped with Er and Yb.

FIG. 7 An outline perspective view showing an optical amplifier obtained in Example 1.

FIG. 8 A cross-sectional diagram taken on B-B in FIG. 7.

FIG. 9 An outline perspective view showing an optical amplifier obtained in Example 3.

FIG. 10 A cross-sectional diagram taken on C-C in FIG. 9.

FIG. 11 An outline perspective view showing an optical amplifier obtained in Example 4.

FIG. 12 A cross-sectional diagram taken on D-D in FIG. 11.

FIG. 13 An outline plane view showing an optical amplifier obtained in Example 5.

FIG. 14 A cross-sectional diagram taken on E-E in FIG. 13.

### BEST MODE FOR CARRYING OUT THE INVENTION

Hereinafter, the present invention will be described in detail.

The optical amplifier of the present invention includes an optical waveguide layer, the optical waveguide layer including Pb₁₋ₓLaₓ(Zr_{y}Ti_{1-y}O_{1-x/4} O₃ (PLZT: 0<x<0.3, 0<y<1.0), being doped with Yb in an amount of from 0.2 mol % to 11.0 mol % (preferably from 0.2 mol % to 5 mol %), and being a single crystal film formed by solid-phase epitaxial growth. By having such a configuration, the optical amplifier of the invention may be a small size and high efficiency optical amplifier.

In the optical amplifier of the present invention, Er (erbium) is preferably doped in addition to Yb, and the doping amount of Er is preferably 5.0 mol % or less, and particularly preferably 3.0 % mol or less. By having such a configuration, the optical amplifier of the present invention may be a small size and higher efficiency optical amplifier.

These are based on the following findings.

The inventors of the present invention diligently investigated sputtering, MOCVD, and solution methods related to doping PLZT with rare earth elements (for example Er, Yb and the like). Out of these, by studying comparatively a single crystal film formed by epitaxial growth of PLZT formed by using, for example, a solution method which is a method superior in dispersing metal ions in an organometallic compound solution to uniformity at the molecular level, and crystallizing while maintaining such a state, the inventors made new insights relating to doping amounts. By, furthermore, trial production of PLZT optical waveguide type optical amplifiers, the inventors arrived at the present invention.

That is, by fabricating PLZT solid-phase epitaxial single crystal films using the solution method as follows, the differences and the doping amounts were investigated and the insights below were discovered.

First, for example, 2-methoxyethanol (CH₃OCH₂CH₂OH:MOE) was added to Pb(CH₃COO)₂, and an alcohol exchange reaction was carried out by reflux heating. Then vacuum distillation was carried out, and removal of byproduct 2-methoxyethyl acetate was promoted. Next, an MOE solution of Zr(O-i-C₃H₇)₄, Ti(O-i-C₃H₇)₄, Yb(O-i-C₃H₇)₃, and Er(O-i-C₃H₇)₃ was added, and an alcohol exchange reaction was carried out by reflux heating. Then vacuum distillation was carried out, and removal of byproduct 2-methoxyethyl acetate was promoted. A precursor solution was prepared by solvent elimination from the obtained product, re-adding MOE and adjusting the precursor concentration.

A PLZT solid-phase epitaxial single crystal film doped with a suitable amounts of Yb and Er was obtained by spin coating the obtained precursor solution onto a SrTiO₃ (100) substrate, then, after amorphizing in a RTA (Rapid Thermal Annealing) furnace, carrying out solid-phase epitaxial growth.

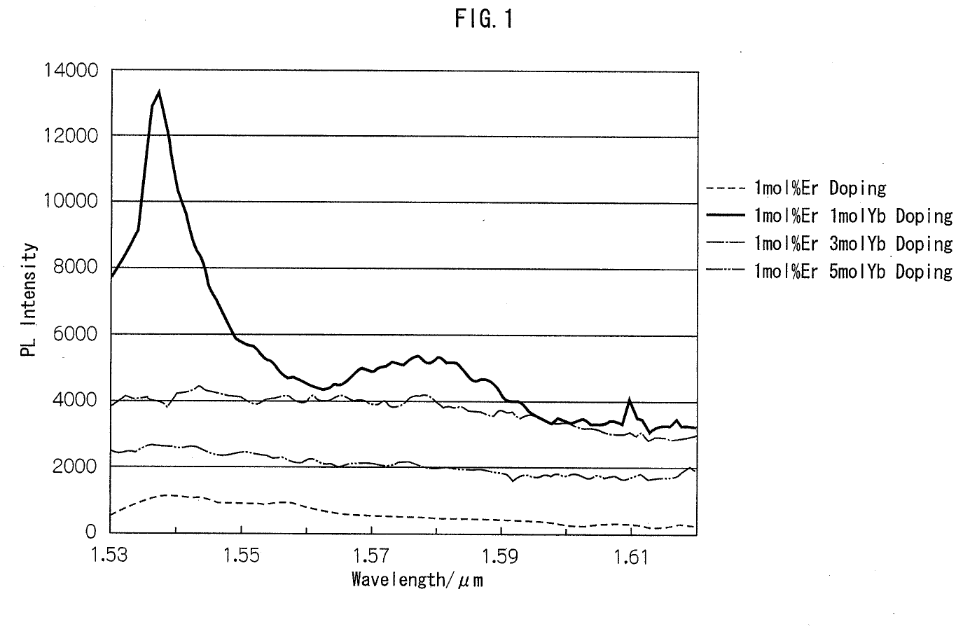

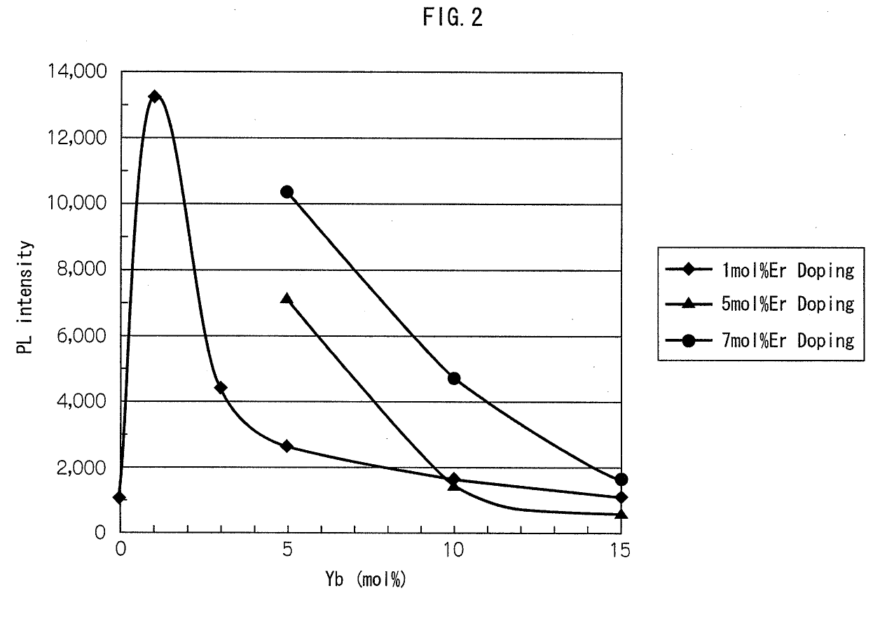

In the Yb-doped PLZT solid-phase epitaxial single crystal films, neither a precipitated phase nor a pyrochlore phase was generated until the Yb-doping amount (adding amount) exceeds 10 mol %, and therefore, it was found that Yb-doping at a doping amount dramatically higher than that of conventional film forming methods is enabled. Further, when photoluminescence was measured for an Yb-doped PLZT solid-phase epitaxial single crystal film, as seen in the photoluminescence spectra in FIG. 1, it was found that when a PLZT doped with 1 mol % of Er is doped with Yb, the photoluminescence intensity (PL intensity) substantially increases. It was also found that, in the examples of the photoluminescence spectrum shown in FIG. 1, flat amplification effects can be expected over the range of from 1.53 μm to 1.56 μm, which is called as “C band” in the communication wavelength band, and of 1.56 to 1.62 μm, which is called as “L band” in the communication wavelength band. Further, with respect to the relationships of the Yb-doping amount and the photoluminescence intensity, as seen in the Yb doping amount versus the fluorescence intensity shown in FIG. 2, when the Yb-doping amount is 11 mol % or less, and particularly 5 mol % or less, significant photoluminescence intensity enhancing effects can be obtained.

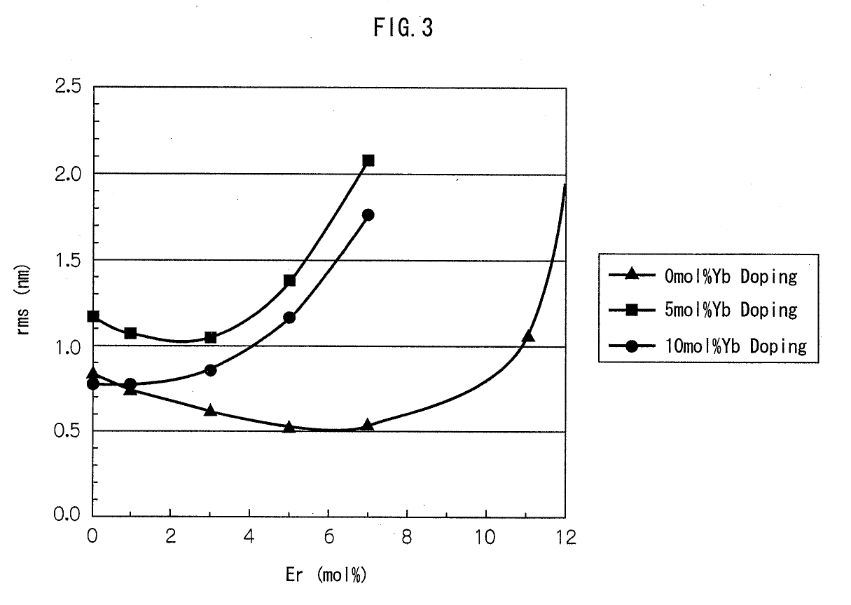

When the surface of the PLZT solid-phase epitaxial single crystal film doped with Yb and Er obtained as described above was examined with an atomic force microscope, as shown in FIG. 3, when the Yb-doping amount is 10 mol % or less, even if the Er-doping amount is about 5 mol %, the surface roughness (rms) is 1.5 μm or less and a significant increase is not shown, and therefore, it can be estimated that scattering loss due to the surface roughness may not be high when an optical waveguide layer is formed. Accordingly, it was found that for an optical amplifier of PLZT optical waveguide layer type, the upper limit of Yb-doping amount is preferably 11 mol % or less, and particularly preferably 5 mol % or less. Further, the upper limit of Er-doping amount is preferably 5 mol % or less, and particularly preferably 3 mol % or less.

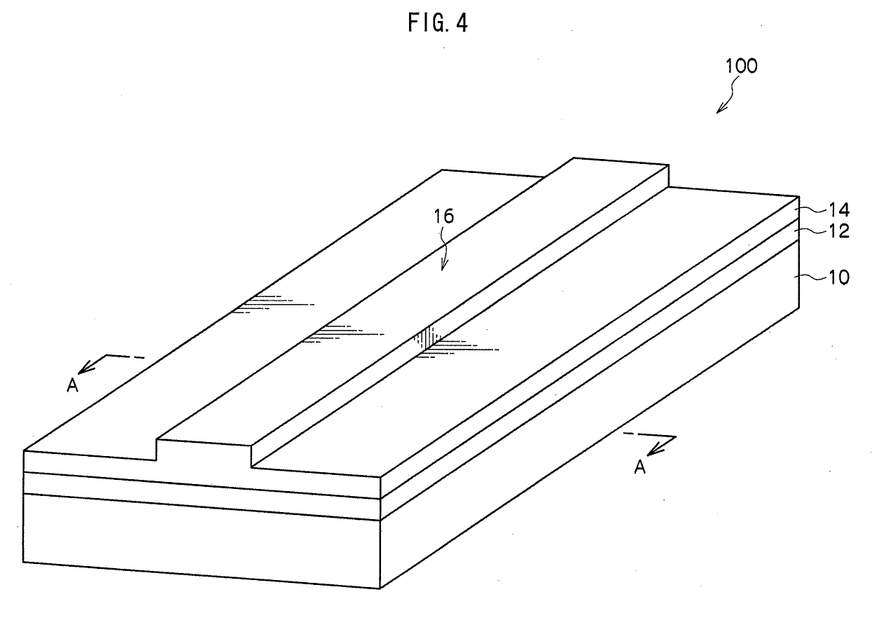

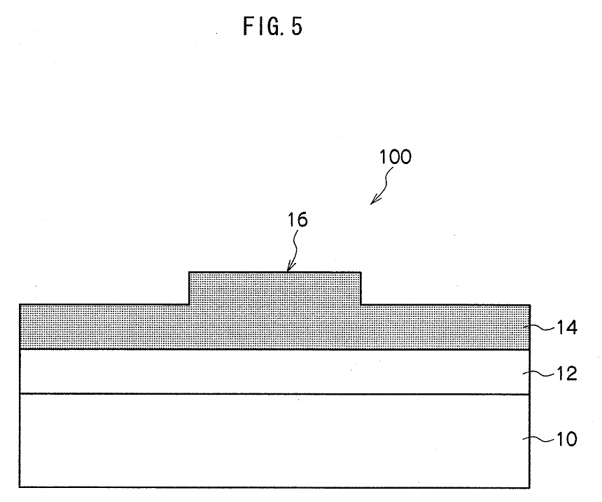

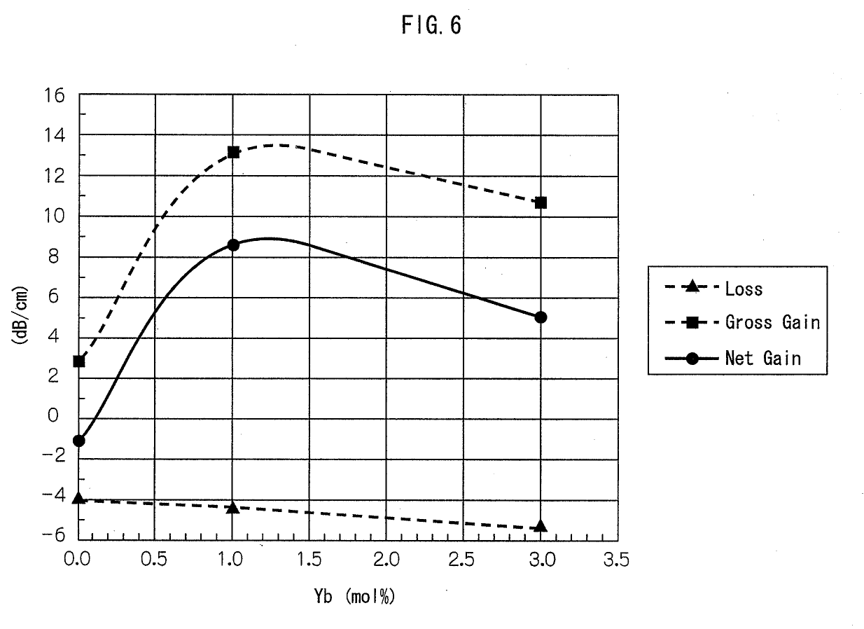

An optical amplifier with a rib channel-shaped optical waveguide layer as shown in FIG. 4 and FIG. 5 was produced in the following manner. First, a 2.3 μm film thickness epitaxial PLZT buffer layer 12 was grown on a SrTiO₃ substrate 10, then a 2.3 μm thick epitaxial Er 1 mol %-Yb-doped PZT slab optical waveguide layer 14 was solid-phase epitaxially grown in the same way as above. Then ICP etching was carried out on the Er1 mol %-Yb-doped PZT slab optical waveguide layer 14 to a depth of 1.0 μm, and a width of 2.8 μm, and a straight line rib channel-shaped optical waveguide layer 16 was formed. A laser beam having a wavelength of 1.55 μm as a signal beam and a laser beam having a wavelength of 1.48 μm as a pump beam were introduced into the channel-shaped optical waveguide layer 16, and in response to pump beam power the 1.55 μm signal beam intensity was measured. The results for respective Yb-doping amounts are shown in FIG. 6. As can be seen from FIG. 6, the gross gain for a pump beam power of 60 mW increased with an increase in the Er-doping amount, and in an Yb-doping amount of 1.0 mol % there was an extremely high efficiency of 13.0 dB/cm. The waveguide loss also somewhat increased with an increase in the Yb-doping amount, and the maximum value of the net gain, which is obtained by subtracting the waveguide loss from the gross gain, was obtained as 8.5 dB/cm at around the Yb-doping 1 mol % level. From this result, it was found that when the Yb is less than 0.2 mol %, the net gain is not obtained, and when Yb is 0.2 mol % or higher, the net gain is obtained.

From the above knowledge, it can be seen that the optical amplifier of the present invention is a small size and high efficiency optical amplifier.

Explanation of the details of the optical amplifier according to the present invention and the production method thereof will be given below.

The optical amplifier of the present invention is configured, for example, with a buffer layer, an optical waveguide layer, and a cladding layer formed in that order on a substrate. However, by combinations and the like with substrates, the configuration may be one of a buffer layer and an optical waveguide layer, an optical waveguide layer and a cladding layer, or even an optical waveguide layer on its own.

Explanation will first be given of the substrate. Appropriately used substrates include, for example: conductive or semiconductive single crystal substrates; or substrates of an epitaxial, or single orientation, conductive or semiconductive film provided on an insulating substrate.

As a conductive or semi-conductive substrate material the following may be used: SrTiO₃ doped with Nb, La or the like; oxides such as Al doped ZnO, In₂O₃, RuO₂, BaPbO₃, SrRuO₃, YBa₂Cu₃O₇₋ₓ, SrVO₃, LaNiO₃, La_{0.5}Sr_{0.5}CoO₃, ZnGa₂O₄, CdGa₂O₄, CdGa₂O₄, Mg₂TiO₄ , MgTi₂O₄ , and the like; elemental semi-conductors such as Si, Ge, diamond and the like; Group III-V compound semi-conductors such as AlAs, AlSb, AlP, GaAs, GaSb, InP, InAs, InSb, AlGaP, AlLnP, AlGaAs, AlInAs, AlAsSb, GaInAs, GaInSb, GaAsSb, InAsSb and the like; Group II-VI compound semiconductors such as ZnS, ZnSe, ZnTe, CaSe, CdTe, HgSe, HgTe, CdS and the like; and metals such as Pd, Pt, Al, Au, Ag and the like.

When providing an epitaxial, or single orientation, conductive or semi-conductive film onto an insulating substrate surface, materials that may be used for the insulating substrate include oxides such as SrTiO₃, BaTiO₃, BaZrO₃, LaAlO₃, ZrO₂, Y₂O₃8%-ZrO₂, MgO, MgAl₂O₄, LiNbO₃, LiTaO₃, Al₂O₃, ZnO and the like. Examples of materials which may be used for a conductive or semi-conductive film, are the same sorts of materials as the above conductive or semi-conductive substrate materials, and these materials may be used to form an epitaxial, or single orientation, conductive or semi-conductive film.

Next, the optical waveguide will be explained. For the optical waveguide layer, a rare earth-doped PLZT single crystal film is used, formed as above by solid-phase epitaxial growth. Here, for Pb₁₋ₓLaₓ(Zr_{y}Ti_{1-y})_{1-x/4} O₃(0<x<0.3, 0<y<1.0), depending on the values of x and y, all of PT, PZT, PLT, PLZT are referred to with the general expression “PLZT”.

For the rare earth element for doping, Yb is used, and in addition to this, Er may be used together with Yb. Another rare earth element such as Nd, Tm, Ho, Pr or the like may be used together. Only one kind of these rare earth elements may be used or two or more kinds of rare earth elements may be used in combination.

The film thickness of the optical waveguide layer may be set, for example, in the range of from 0.1 μm to 10 μm, however, the thickness may be suitably selected according to the purpose.

The optical waveguide layer may be any type of the generally used embedded, ridge, or rib types, in other words an optical waveguide layer having a channel-shaped optical waveguide layer patterned in the desired shape may be used (referred to below as a channel optical waveguide structure). Such a channel optical waveguide structure may be a structure of a slab optical waveguide layer and a channel-shaped optical waveguide layer, or it may be a structure just of a channel-shaped optical waveguide layer.

Preferable specific examples that can be given of channel optical waveguide structures include: channel optical waveguide structures in which a protrusion is provided on an optical waveguide layer; channel optical waveguide structures in which a cladding layer is provided after providing a protrusion on an optical waveguide layer; and channel optical waveguide structures in which a recess is made in a buffer layer and then an optical waveguide layer is provided. Such structures may easily be obtained by disposing thin films, for example, providing an epitaxial or single orientation buffer layer, and providing on this an optical waveguide layer having epitaxial with a refractive index greater than that of the buffer layer.

Next, the buffer layer will be explained. The buffer layer may be formed with materials having a smaller refractive index than that of the optical waveguide layer material. Also, it is preferable that the buffer layer is able to maintain an epitaxial relationship to the substrate material and the optical waveguide layer material. With respect to the conditions for maintaining such an epitaxial relationship, the crystal structure of the buffer layer material is preferably similar to that of the substrate material and that of the optical waveguide layer material, and it is also preferable that the difference in lattice constants is 10% or less. However, as long as such an epitaxial relationship may be maintained then such relationships do not necessarily need to be fulfilled. Specifically, the buffer layer material may be, for example, PLZT, or may be selected from, for example, SrTiO₃, BaTiO₃, (Sr₁₋ₓBaₓ) TiO₃, (0<x<1.0), KNbO₃ and the like.

Next, the cladding layer will be explained. The cladding layer may be formed with materials having a smaller refractive index than that of the optical waveguide layer material. Also, it is not always necessary for the cladding layer to be able to maintain an epitaxial relationship to the optical waveguide layer, and a polycrystal film or amorphous substance may be used. Specifically, the cladding layer material may be, for example, PLZT, or may be selected from, for example, SrTiO₃, BaTiO₃, (Sr₁₋ₓBaₓ) TiO₃, Pb(Mg_{1/3}Nb_{2/3})O₃, KNbO₃, SiO₂, Al₂O₂, TaO₂, polymers and the like.

Here, when the buffer layer and or the cladding layer are configured to include PLZT then rare earth elements may be contained therein. Furthermore, the optical waveguide layer, buffer layer, cladding layer may be configured to include compositions of PLZT that are different from each other. By changing the proportion of a rare earth element added to the PLZT compositions, that is to say Pb, La, Zr, and Ti, as well as the proportion of the PLZT compositions, the refractive index can be changed by a large amount, and PLZT may be used for various layer materials.

Next, explanation will be given of the production method of the optical amplifier of the present invention. The optical amplifier of the present invention may be obtained by processing including at least: an amorphous film forming step, forming an amorphous film as a precursor for an optical waveguide layer; and a crystallization step, heating the amorphous film to crystallize to form an optical waveguide layer by solid-phase epitaxial growth.

Specifically, the optical waveguide layer may be formed by: forming an amorphous film for an optical waveguide layer using vapor-phase epitaxial growth using a vapor phase growth (vapor deposition) method selected from electron beam vapor deposition, flash vapor deposition, ion plating, Rf-magnetron sputtering, ion beam sputtering, laser ablation, a molecular beam epitaxial method (MBE), a chemical vapor deposition method (CVD), plasma CVD, an metal organic chemical vapor deposition method (MOCVD) and the like; or a wet process such as a sol gel method, a metal organic deposition (MOD) method, or the like (amorphous film forming step); then heating the amorphous film to crystallize to form the optical waveguide layer by solid-phase epitaxial growth using a solid-phase growth method (crystallization step). Forming the optical waveguide layer by solid-phase epitaxial growth, is preferable from the point of view of, in addition to enabling doping with a high concentration of a rare earth element, as described above, the quality of the waveguide and waveguide patterning. The buffer layer and the cladding layer may also be formed in a similar manner.

Among the above described methods, the solid-phase epitaxial growth by carrying out the amorphous film forming step by coating an optical waveguide layer precursor solution of an organometallic compound, such as a metal alkoxide, organometallic salt or the like, onto a substrate by wet processes such as sol gel methods, MOD methods and the like and heating, and carrying out the crystallization step by heating, are lower in facility costs compared to various vapor phase growth methods. Also, not only with the method is there good uniformity within the plane of the substrate, but also, by simply formulating the compositions of the organometallic compound precursor according to the composition of films having the necessary refractive indices of the buffer layer, the optical waveguide layer, and the cladding layer, easy control may be made of these refractive indices that are important for structural control of the buffer layer, the optical waveguide layer and the cladding layer. Also good reproducibility is possible, and growth of buffer layers, optical waveguide layers and cladding layers with low optical transmission loss is possible, and furthermore, because rare earth element doping with uniformity at the atomic level and without formation of clusters is possible, this method is extremely effective.

The organometallic compounds used in the above wet processes may be selected from metal alkoxides and metal salts, which are the reaction products of various metals (including rare earth elements) and organic compounds (preferably organic compounds with boiling points of 80° C. or above), however, there is no limitation to such. As organic ligands for the organometallic compounds R₁O- or R₂OR₃O- may be selected (wherein R₁ and R₂ represent aliphatic hydrocarbon groups, and R₃ represents a divalent aliphatic hydrocarbon group that may have an ether bond).

Metals and organic compounds that are the raw materials may be reacted with a solvent of a particular composition selected from alcohols, diketones, keto acids, alkyl esters, hydroxy acids, oxyketones, acetic acid and the like (preferably a solvent with a boiling point of 80° C. or above), or dissolved in a solvent, and then coated onto a single crystal substrate. Organometallic compounds may also be coated after hydrolyzing, but in order to obtain a solid-phase epitaxial film with good characteristics, it is preferable not to hydrolyze. Also, from the perspective of the quality of the film obtained, these reactions are preferably carried in a dry nitrogen or argon atmosphere.

Metal alkoxide compounds contain a metal and may be synthesized by carrying out distillation and refluxing of an organic solvent represented by R₁OH or R₂OR₃OH. R₁ and R₂ represent aliphatic hydrocarbon groups, and alkyl groups with 1 to 4 carbon atoms are preferable as R₁ and R₂, and R₃ is preferably an alkylene group of 2 to 4 carbon atoms, or a divalent group having 4 to 8 carbon atoms in total in which an alkylene group having 2 to 4 carbon atoms is bonded via an ether bond.

For solvents with a boiling point of 80° C. or more, specific examples are solvents which easily carry out an alcohol exchange reaction of the metal alkoxide, for example, alcohols such as (CH₃)₂CHOH (boiling point 82.3° C.), CH₃ (C₂H₅)CHOH (boiling point 99.5° C.), (CH₃)₂CHCH₂OH (boiling point 108° C.), C₄H₉OH (boiling point 117.7° C.), (CH₃)₂CHC₂H₄OH (boiling point 130.5° C.), CH₃OCH₂CH₂OH (boiling point 124.5° C.), C₂H₅OCH₂CH₂OH (boiling point 135° C.), C₄H₉OCH₂CH₂OH (boiling point 171° C.) and the like, are the most preferable, but the solvent is not limited to these, and C₂H₅OH (boiling point 78.3° C.) and the like may be used.

Such a solution containing the organometallic compound may be coated on the substrate with a method selected from spin coating methods, dipping methods, spray methods, screen printing methods, and ink jet methods. From the perspective of the quality of the obtained film, it is preferable that the coating is carried out in a dry nitrogen or argon atmosphere.

After coating the solution containing the organometallic compound, if necessary, as a pre-treatment, processing in an oxygen containing atmosphere (preferably in oxygen) may be carried out by raising the temperature at an increase in temperature rate of 0.1 to 1000° C. per second (preferably at an increase in temperature rate of 1 to 100° C. per second) and heating the substrate within the temperature range in which crystallization does not occur of 100° C. to 500° C. (preferably 200° C. to 400° C.), thereby forming the amorphous film by thermal decomposition of the coating layer.

In addition, solid-phase epitaxial growth of the amorphous film is caused from the surface of the substrate by, in an oxygen containing atmosphere (preferably in oxygen), raising the temperature at an increase in temperature rate of 1 to 500° C. per second (preferably at an increase in temperature rate of 10 to 100° C. per second) and heating within the temperature range of 500° C. to 1200° C. (preferably 600° C. to 900° C.). In this crystallization step, heating is carried out in the above temperature range for from 1 second to 24 hours, preferably from 1 second to 12 hours. Also, from the perspective of the quality of the film obtained, it is preferable to use an oxygen atmosphere that has been dried for a certain amount of time, however, humidification of the atmosphere may also be carried out, if necessary.

The thickness of a film formed by carrying out solid-phase epitaxial growth one time is from 10 nm to 1000 nm, and is preferably from 10 nm to 200 nm. By repeatedly carrying out the above solid-phase epitaxial growth it is possible to obtain a film of the desired thickness. Here, when solid-phase epitaxial growth is carried out repeatedly, it is preferable to carry out cooling at a cooling rate of 0.01 to 100° C. per second after each solid-phase epitaxial growth.

In the production method of the optical amplifier of the present invention, when the optical waveguide layer has a channel-shaped optical waveguide layer, then etching may be carried out of at least one portion of the amorphous film or of the optical waveguide layer, forming the channel-shaped optical waveguide layer.

When forming a channel-shaped optical waveguide layer by etching in the amorphous film condition, crystallizing and causing solid-phase epitaxial growth, extremely smooth edges, side walls and surfaces, with very little optical loss by scattering, may be obtained. Also, by such a solid-phase epitaxial growth method, not only is there good uniformity within the plane of the substrate, compared to various vapor phase growth methods, but also there is the advantages that the refractive index of the film may be easily controlled, by the composition of the organometallic compound precursor, and good reproducibility may be achieved.

When forming a channel-shaped optical waveguide layer by crystallization of the amorphous film and causing solid-phase epitaxial growth, an optical waveguide layer with excellent crystallinity may be obtained. Further, when, after forming a channel-shaped optical waveguide layer by patterning in a predetermined channel pattern, a cladding layer is etched, the optical waveguide layer may also etched in the etching of the cladding layer, which may result in a lowering in fabrication accuracy of the channel-shaped optical waveguide layer. However, in this method, after etching the cladding layer, the optical waveguide layer is patterned in a predetermined channel-shaped pattern to form a channel-shaped optical waveguide layer, and therefore, a channel-shaped optical waveguide layer may be formed with good accuracy.

Here, with respect to the etching of the amorphous film or the optical waveguide layer, the etching speed is fast, the etching may be easily stopped, and the controllability of etching is good. Specifically, after coating the surface of the amorphous film with a photoresist or electron beam resist, patterning of the amorphous film can be made by carrying out sequentially light exposure, developing, etching, and removal of the resist.

The etching method may be any of: wet etching, by aqueous solutions of HCl, HNO₃, HF, H₂SO₄, H₃PO₄, C₂H₂O₂, NH₄F and the like, or mixtures thereof; or dry etching such as by reactive ion etching by gases such as CCl₄, CCl₂F₂, CHClFCF₃, and mixtures of these gases with O₂; or dry etching such as ion beam etching and the like. The wet etching is preferable since processing with good accuracy in a short time period is enabled.

The optical amplifier of the present invention may be produced as described above.

### EXAMPLES

The present invention will be explained below by way of examples. However, these examples do not limit the present invention.

### Example 1

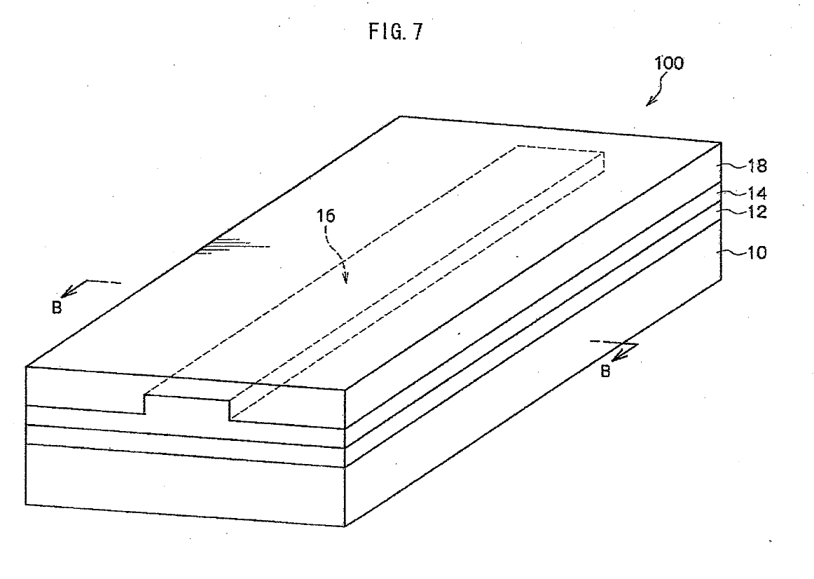

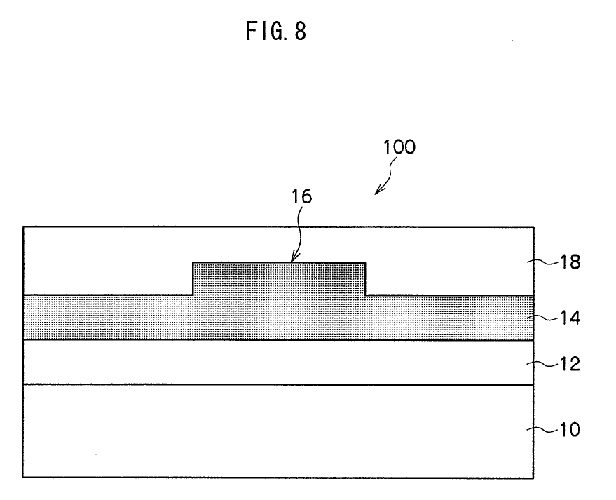

In the present example, as will be described below, an optical amplifier using a rib optical waveguide layer as shown in FIG. 7 and FIG. 8 was produced. The optical amplifier 100, as shown in FIG. 7 and FIG. 8, is provided sequentially with a buffer layer 12, a slab optical waveguide layer 14, and a channel-shaped optical waveguide layer 16, in that order, on a substrate 10. Furthermore, a cladding layer 18 is provided so as to cover the slab optical waveguide layer 14 and the channel-shaped optical waveguide layer 16.

First, 2-methoxyethanol (CH₃OCH₂CH₂OH:MOE) was added to Pb(CH₃ COO)₂, and an alcohol exchange reaction was carried out by reflux heating. Then vacuum distillation was carried out, and removal of byproduct 2-methoxyethyl acetate was promoted. Next, an MOE solution of La (O-i-C₃H₇)₃, Zr(O-i-C₃H₇)₄, Ti(O-i-C₃H₇)₄ was added and an alcohol exchange reaction was carried out by reflux heating. Then vacuum distillation was carried out, and removal of by product 2-methoxyethyl acetate was promoted. A precursor solution was prepared by solvent elimination from the obtained product, re-adding MOE and adjusting the precursor concentration.

The obtained precursor solution was spin coated onto a Nb-doped SrTiO₃ (100) wafer (substrate 10) then, after amorphizing, crystallization and solid-phase epitaxial growth was carried out a number of times in a RTA (Rapid Thermal Annealing) furnace, and an epitaxial Pb₁₋ₓLaₓ(Zr_{y}Ti_{1-y})_{1-x/4} O₃ (x=0.04, y=0.78) buffer layer 12 was formed at a thickness of 2.3 μm.

Next, in the same way, an MOE precursor solution synthesized from Pb(CH₃COO)₂, Zr(O-i-C₃H₇)₄, Ti(O-i-C₃H₇)₄, Er(O-i-C₃H₇)₃ and Yb(O-i-C₃H₇)₃ was spin coated on the buffer layer 12, and, after amorphization, crystallization and solid-phase epitaxial growth was carried out in a RTA furnace, and an epitaxial Er 1.0 mol %, Yb 3.0 mol %: Pb(Zr_{y}Ti_{1-y})_{1-x/4} O₃ (x=0, y=0.52) slab optical waveguide layer 14 was formed at a thickness of 2.4 μm. Then ICP etching was carried out on the slab optical waveguide layer 14 (Er-doped PZT optical waveguide layer) to a depth of 1.2 μm, and a width of 2.8 μm, and a straight line rib channel-shaped optical waveguide layer 16 was formed.

Further, a 1.0 μm thick SiO₂ cladding layer 18 was formed by sputtering so as to cover the slab optical waveguide layer 14 and the channel-shaped optical waveguide layer 16.

Then, after dicing the wafer, the light input and output end faces were polished, and an optical amplifier chip of length 2 cm was completed.

A laser beam having a wavelength of 1.55 μm as a signal beam, and a laser beam having a wavelength of 1.48 μm as a pump beam were introduced into the chip core, and in response to pump beam power the 1.55 μm signal beam intensity was measured, and for a pump beam power of 60 mW a net gain of the 1.55 μm signal beam of 11 dB, or 5.5 dB/cm, was obtained. Further, in this doping proportion, flat amplification effect over the C band and L band was obtained. It is considered this is because the photoluminescence spectrum has properties such that the photoluminescence spectrum is flat as shown in FIG. 1.

### Comparative Example 1

In Comparative Example 1, an optical amplifier was obtained in the same way as that of Example 1, apart from the following changes.

First a 2.3 μm film thickness Pb₁₋ₓLaₓ(Zr_{y}Ti_{1-y})_{1-x/4} O₃ (x=0.04, y=0.78) buffer layer 12 was solid-phase epitaxially grown on a Nb-doped SrTiO₃ (100) wafer (substrate 10), then a 23 μm thick Er 1.0 mol %, Yb 0.15%: Pb(Zr_{y}Ti_{1-y})_{1-x/4} O₃ (x=0, y=0.52) slab optical waveguide layer 14 was epitaxially grown. Then ICP etching was carried out on the slab optical waveguide layer 14 (PZT optical waveguide layer doped with Er and Yb) to a depth of 1.2 μm, and a width of 2.8 μm, and a straight line rib channel-shaped optical waveguide layer 16 was formed, and a 1.0 μm SiO₂ cladding layer 18 was formed by sputtering.

After this, after dicing the wafer, the light input and output end faces were polished, and an optical amplifier chip of length 2 cm was completed. A laser beam having a wavelength of 1.55 μm as a signal beam, and a laser beam having a wavelength of 1.48 μm as a pump beam were introduced into the chip core, and in response to pump beam power the 1.55 μm signal intensity was measured, and for a pump beam power of 60 mW no net gain of the 1.55 μm signal beam was not obtained since the amplification effect was insufficient for compensating the waveguide loss.

### Comparative Example 2

In Comparative Example 2, an optical amplifier was obtained in the same way as that of Example 1, apart from the following changes.

First a 2.3 μm film thickness Pb₁₋ₓLaₓ(Zr_{y}Ti_{1-y})_{1-x/4} O₃ (x=0.04, y=0.78) buffer layer 12 was solid-phase epitaxially grown on a Nb-doped SrTiO₃ (100) wafer (substrate 10), then a 2.3 μm thick Er 3.5 mol %, Yb 12.0 mol % : Pb(Zr_{y}Ti_{1-y})_{1-x/4} O₃ (x=0, y=0.52) slab optical waveguide layer 14 was solid phase epitaxially grown. Then ICP etching was carried out on the slab optical waveguide layer 14 (Er-doped PZT optical waveguide layer) to a depth of 1.2 μm, and a width of 2.8 μm, and a straight line rib channel-shaped optical waveguide layer 16 was formed, and a 1.0 μm SiO₂ cladding layer 18 was formed by sputtering.

After this, after dicing the wafer, the light input and output end faces were polished, and an optical amplifier chip of length 2 cm was completed. A laser beam having a wavelength of 1.55 μm as a signal beam, and a laser beam having a wavelength of 1.48 μm as a pump beam were introduced into the chip core, and in response to pump beam power the 1.55 μm signal beam intensity was measured, and for a pump beam power of 60 mW no net gain of the 1.55 μm signal beam was not obtained since the waveguide loss increases due to the absorption of Er around 1.55 μm and the amplification effect was insufficient.

### Example 2

In Example 2, an optical amplifier was obtained in the same way as that of Example 1, apart from the following changes.

First a 2.4 μm film thickness Pb₁₋ₓLaₓ(Zr_{y}Ti_{1-y})_{1-x/4} O₃ (x=0.09, y=0.65) buffer layer 12 was solid-phase epitaxially grown on a Nb-doped SrTiO₃ (100) wafer (substrate 10), then a 2.8 μm thick Er 2.0 mol %, Yb 5.0 mol %: Pb₁₋ₓLaₓ(Zr_{y}Ti_{1-y})_{1-x/4} O₃ (x=0.03, y=0.52) slab optical waveguide layer 14 was solid-phase epitaxially grown. Then ICP etching was carried out on the slab optical waveguide layer 14 (Er-doped PZT optical waveguide layer) to a depth of 1.0 μm, and a width of 3.0 μm, and a straight line rib channel-shaped optical waveguide layer 16 was formed, and a 1.0 μm SiO₂ cladding layer 18 was formed by sputtering.

After this, after dicing the wafer, the light input and output end faces were polished, and an optical amplifier chip of length 2 cm was completed. A laser having a wavelength of 1.55 μm as a signal beam, and a laser beam having a wavelength of 1.48 μm as a pump beam were introduced into the chip core, and in response to pump beam power the 1.55 μm signal beam intensity was measured, and for a pump beam power of 60 mW a net gain of the 1.55 μm signal beam of 9 dB or 4.5 dB/cm was obtained. Further, in this doping proportion, flat amplification effect over the C band and L band was obtained.

### Example 3

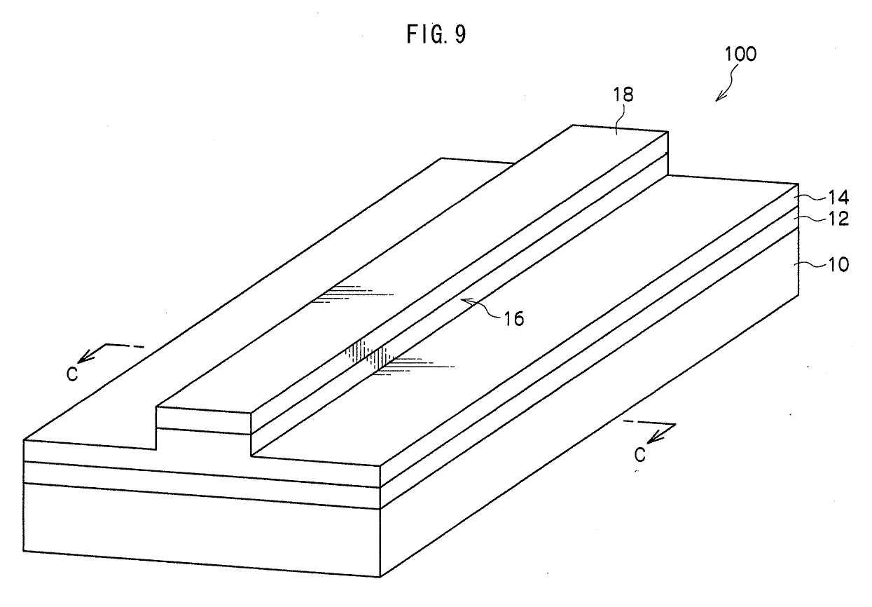

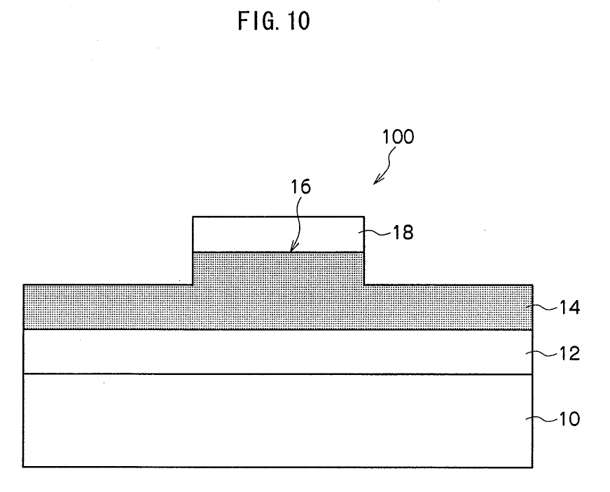

In the present example, as will be described below, an optical amplifier using a rib optical waveguide layer as shown in FIG. 9 and FIG. 10 was produced. The optical amplifier 100, as shown in FIG. 9 and FIG. 10, is provided sequentially with a buffer layer 12, a slab optical waveguide layer 14, and a channel-shaped optical waveguide layer 16, in that order, on a substrate 10. Furthermore, a cladding layer 18 is provided on the channel-shaped optical waveguide layer 16.

Apart from changes in the composition, in the same manner as in Example 1, a 2.0 μm film thickness Pb₁₋ₓLaₓ(Zr_{y}Ti_{1-y})_{1-x/4} O₃ (x=0.04, y=0.78) buffer layer 12 was solid-phase epitaxially grown on a Nb-doped SrTiO₃ (100) wafer (substrate 10), then a 2.0 μm film thickness Yb 6.0 mol %: Pb₁₋ₓLaₓ(Zr_{y}Ti_{1-y})_{1-x/4} O₃ (x=0.06, y=0.61) slab optical waveguide layer 14 was epitaxially grown.

Further, a 1.0 μm thick Pb₁₋ₓLaₓ(Zr_{y}Ti_{1-y})_{1-x/4} O₃ (x=0.04, y=0.78) cladding layer 18 was solid-phase epitaxially grown, and ICP etching was carried out on the slab optical waveguide layer 14 to a depth of 1.7 μm, and a width of 2.8 μm, and a straight line rib channel-shaped optical waveguide layer 16 was formed. Here, etching was also performed on the cladding layer 18, and patterning was carried out.

Then, after dicing the wafer, the light input and output end faces were polished, and an optical amplifier chip of length 2 cm was completed. A laser beam having a wavelength of 1.55 μm as signal beam, and a laser beam having a wavelength of 1.48 μm as a pump beam were introduced into the chip core, and in response to pump beam power the 1.55 μm signal beam intensity was measured, and for a pump beam power of 60 mW a net gain of the 1.55 μm signal beam of 4 dB, or 2.0 dB/cm, was obtained. It is considered that the reason for the less impact of Yb on the waveguide loss than that of Er is that the absorption of Yb is present around 1.0 μm.

### Example 4

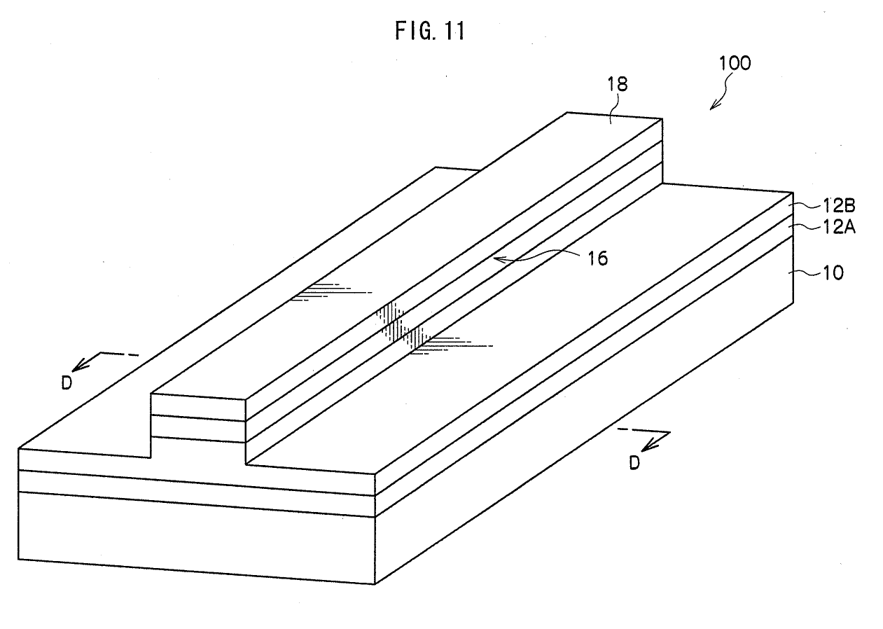

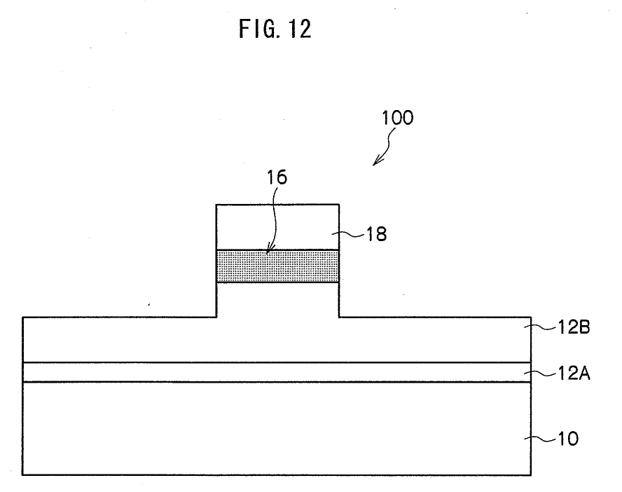

In the present example, as will be described below, an optical amplifier using a rib optical waveguide layer as shown in FIG. 11 and FIG. 12 was produced. The optical amplifier 100, as shown in FIG. 11 and FIG. 12, is provided sequentially with a first buffer layer 12A (slab buffer layer), a second buffer layer 12B (convex buffer layer in which a channel-shaped buffer layer is disposed on a slab buffer layer), and a channel-shaped optical waveguide layer 16, in that order, on a substrate 10. Furthermore, a cladding layer 18 is provided on the channel-shaped optical waveguide layer 16.

As the first buffer layer 12A, MgO was epitaxially grown on a Si wafer (substrate 10) using an ion beam sputtering method. Then, apart from changes in the composition, in the same manner as in Example 1, as a second buffer layer 12B a Er 0.5 mol %, Yb 0.2 mol % Pb₁₋ₓLaₓ(Zr_{y}Ti_{1-y})_{1-x/4} O₃ (x=0.04, y=0.78) was solid-phase epitaxially grown, then an Er 0.5 mol %, Yb 0.2 mol %: Pb₁₋ₓLaₓ(Zr_{y}Ti_{1-y})_{1-x/4} O₃ (x=0.06, y=0.61) slab optical waveguide layer was solid-phase epitaxially grown. Further, a Er 0.5 mol %, Yb 0.2 mol % : Pb₁₋ₓLaₓ(Zr_{y}Ti_{1-y})_{1-x/4} O₃ (x=0.04, y=0.78) cladding layer 18 was solid-phase epitaxially grown.

ICP etching was carried out to a width of 2.8 μm, and a straight line rib channel-shaped optical waveguide layer 16 was formed. Here, etching was also performed on the buffer layer 12B and the cladding layer 18, and patterning was carried out.

Then, after dicing the wafer, the light input and output end faces were polished, and an optical amplifier chip of length 2 cm was completed. A laser beam having a wavelength of 1.55 μm as a signal beam, and a laser beam having a wavelength of 0.98 μm as a pump beam were introduced into the chip core, and in response to pump beam power the 1.55 μm signal beam intensity was measured, and efficient net gain was obtained. Further, in this doping proportion, flat amplification effect over the C band or the L band was obtained.

### Example 5

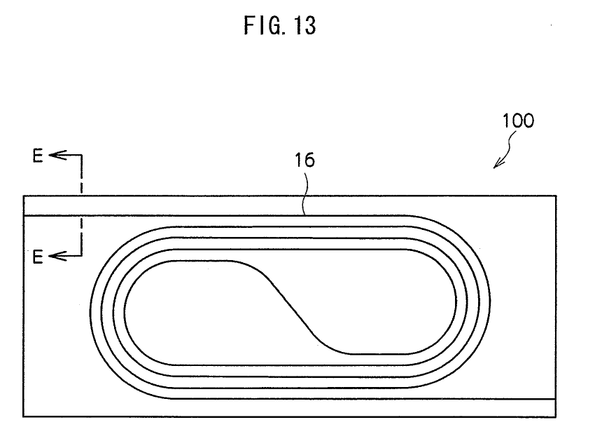

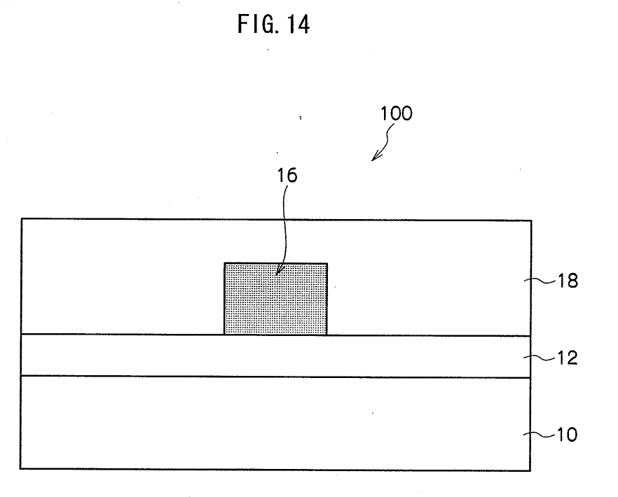

In the present example, as will be described below, an optical amplifier using a rib optical waveguide layer as shown in FIG. 13 and FIG. 14 was produced. The optical amplifier 100, as shown in FIG. 13 and FIG. 14, is provided sequentially with a buffer layer 12, and a channel-shaped optical waveguide layer 16, in that order, on a substrate 10. Furthermore, a cladding layer 18 is provided so as to cover the channel-shaped optical waveguide layer 16. In the optical amplifier 100 shown in FIG. 13 and FIG. 14, the channel-shaped optical waveguide layer 16 is provided on the buffer layer 12 such that the waveguide layer is bended and winds.

Apart from changes in the composition, in the same manner as in Example 1, a Pb₁₋ₓLaₓ(Zr_{y}Ti_{1-y})_{1-x/4} O₃ (x=0.28, y=0) buffer layer 12 was solid-phase epitaxially grown on a sapphire wafer (substrate 10), then a Yb 11.0 mol %: Pb₁₋ₓLaₓ(Zr_{y}Ti_{1-y})_{1-x/4} O₃ (x=0.03, y=0.52) slab optical waveguide layer was solid-phase epitaxially grown.

Then ICP etching was performed on the slab optical waveguide layer (Yb-doped PZT optical waveguide layer), an embedded channel-shaped optical waveguide layer 16 was formed, arranged in a curvilinear shape such that its total length was about 10 cm, and further a SiO₂ cladding layer 18 was formed by sputtering.

Then, after dicing the wafer, the light input and output end faces were polished, and an optical amplifier chip of length 2 cm was completed. A laser beam having a wavelength of 1.55 μm as a signal beam. and a laser beam having a wavelength of 1.48 μm as a pump beam were introduced into the chip core, and in response to pump beam power the 1.55 μm signal beam intensity was measured, and efficient net gain was obtained, although the result is inferior compared with Examples 1 and 2. Further, in this doping proportion, flat amplification effect over the C band and the L band was obtained.

By the above, in the various examples above, is can be seen that the following may be obtained: integration of PLZT optical waveguide devices that have high speeds, low driving voltages, low power consumptions. and small size; miniaturization of optical amplifier units; and small, high efficiency optical amplifiers of optical waveguide type in which a rare earth element is added to PLZT, which are necessary for modularization of smaller and high performance devices in which plural optical amplifier units are integrated or unified, and various modulators, switches, wavedividers and the like are integrated.

### Description of Signs

10 Substrate

12 Buffer layer

14 Slab optical waveguide layer

16 Channel-shaped optical waveguide layer

18 Cladding layer

1. An optical amplifier comprising an optical waveguide layer, the optical waveguide layer comprising Pb₁₋ₓLaₓ(Zr_{y}Ti_{1-y})_{1-x/4}O₃ (PLZT: 0<x<0.3, 0<y<1.0), being doped with Yb (ytterbium) in an amount of from 0.2 mol % to 11.0 mol %, and being a single crystal film formed by solid-phase epitaxial growth.

2. The optical amplifier according to claim 1, wherein the optical waveguide layer is doped with Er (erbium) in an amount of 3.0 mol % or less.

3. The optical amplifier according to claim 1, comprising a buffer layer and a cladding layer in addition to the optical waveguide layer, wherein the optical waveguide layer, the buffer layer and the cladding layer each comprise a PLZT composition and the respective PLZT compositions are different from each other.

4. The optical amplifier according to claim 1, wherein the optical waveguide layer comprises a channel-shaped optical waveguide layer.

5. A method of producing the optical amplifier according to claim 1, the method comprising:
forming, on a substrate, an amorphous film as an optical waveguide layer precursor; and
heating the amorphous film to crystallize the film to form the optical waveguide layer by solid-phase epitaxial growth.

6. The optical amplifier production method of claim 5, further comprising performing etching on at least one portion of the amorphous film or the optical waveguide layer, to form a channel-shaped optical waveguide layer.

7. The optical amplifier production method of claim 5, wherein the forming of the amorphous film comprises forming an amorphous film by coating an optical waveguide layer precursor solution onto the substrate, and heating.
